(19) United States
(12) Patent Application Publication
(10) Pub. No.: US 2026/0198150 A1
(43) Pub. Date: Jul. 9, 2026

(54) SEMICONDUCTOR LIGHT-EMITTING ELEMENT AND MANUFACTURING METHOD THEREOF

(71) Applicant: AUO Corporation, Hsinchu City (TW)

(72) Inventor: Tian-Sih Huang, Hsinchu City (TW)

(73) Assignee: AUO Corporation, Hsinchu City (TW)

(21) Appl. No.: 19/300,606

(22) Filed: Aug. 14, 2025

(30) Foreign Application Priority Data
Jan. 9, 2025 (TW) 114100833

(51) Int. Cl. H10H 20/857; H10H 20/01

(52) U.S. Cl. CPC H10H 20/857; H10H 20/0364

(57) ABSTRACT

A semiconductor light-emitting element includes a substrate, an insulating material, multiple conductors, multiple guide structures, multiple solders, and a light-emitting module. The insulating material is formed on the substrate. The conductors are formed on the substrate, and are located on opposite sides of the insulating material. The guide structures are respectively formed on each of the conductors, and are located on opposite sides of the insulating material. Each guide structure has a first guide inclined surface. The solders are respectively disposed on each of the conductors. Each solder is located between the insulating material and the first guide inclined surface. The light-emitting module is disposed on these solders. The solders are located between the light-emitting module and the conductors. A manufacturing method of the semiconductor light-emitting element is also provided.

### CROSS-REFERENCE TO RELATED APPLICATION

This application claims the priority benefit of Taiwan application serial no. 114100833, filed on Jan. 9, 2025. The entirety of the above-mentioned patent application is hereby incorporated by reference herein and made a part of this specification.

### BACKGROUND

### Technical Field

The disclosure relates to a semiconductor light-emitting element and a manufacturing method, and in particular to a semiconductor light-emitting element and a manufacturing method thereof.

### Related Art

In existing semiconductor light-emitting elements, when a solder and a light-emitting module are joined to a conductor, possible deviation of the solder and the light-emitting module may be generated in the previous process. If an angle of the deviation is too large, short circuit or open circuit may easily occur in the process of joining the solder and the light-emitting module to the conductor.

### SUMMARY

The disclosure provides a semiconductor light-emitting element and a manufacturing method thereof, which has extremely high reliability.

A semiconductor light-emitting element of the disclosure includes a substrate, an insulating material, multiple conductors, multiple guide structures, multiple solders, and a light-emitting module. The insulating material is formed on the substrate. The conductors are formed on the substrate, and are located on opposite sides of the insulating material. The guide structures are respectively formed on each of the conductors, and are located at opposite sides of the insulating material. Each guide structure has a first guide inclined surface. The solders are respectively disposed on each of the conductors. Each solder is located between the insulating material and the first guide inclined surface. The light-emitting module is disposed on the solders. The solders are located between the light-emitting module and these conductors.

A manufacturing method of a semiconductor light-emitting element of the disclosure includes following steps. A substrate is provided. An insulating material is formed on the substrate. Multiple conductors are formed on the substrate, and are located on opposite sides of the insulating material. Multiple guide structures are formed on each of the conductors, and are located on opposite sides of the insulating material, where each guide structure has a first guide inclined surface. Multiple solders and a light-emitting module are disposed on the conductors, where each solder is located between an insulating material and a first guide inclined surface, and the solders are located between the light-emitting module and the conductors.

Based on the above, in the semiconductor light-emitting element and the manufacturing method thereof of an embodiment of the disclosure, when being disposed on each of the conductors, the solders may be accurately positioned between the first guide inclined surface and the insulating material by the first guide inclined surface. Therefore, when the solders and the light-emitting module are joined to the conductor, deviation may be effectively avoided, which helps reduce the situations of short circuit or open circuit, and has extremely high reliability.

### BRIEF DESCRIPTION OF THE DRAWINGS

FIG. 1 is a schematic view of a semiconductor light-emitting element of a first embodiment of the disclosure.

FIG. 2 to FIG. 3 are schematic views of the semiconductor light-emitting element of the first embodiment of the disclosure during a joining process.

FIG. 4 is a flow chart of a manufacturing method of the semiconductor light-emitting element of the first embodiment of the disclosure.

FIG. 5 is a schematic view of a semiconductor light-emitting element of a second embodiment of the disclosure.

FIG. 6 is a schematic view of the semiconductor light-emitting element of the first embodiment of the disclosure applied as a display module.

### DESCRIPTION OF THE EMBODIMENTS

Considering the particular amount of measurement and measurement-related errors discussed (i.e., the limitations of the measurement system), the terminology “about,” “approximately,” “essentially,” or “substantially” used herein includes the average of the stated value and an acceptable range of deviations from the particular value as determined by those skilled in the art. For instance, the terminology “about” may refer to as being within one or more standard deviations of the stated value, or within ±30%, ±20%, ±15%, ±10%, or ±5%. Furthermore, the terminology “about,” “approximately,” “essentially,” or “substantially” as used herein may be chosen from a range of acceptable deviations or standard deviations depending on the measurement properties, cutting properties, or other properties, rather than one standard deviation for all properties.

In the accompanying drawings, the thickness of layers, films, panels, regions, and so forth are enlarged for clarity. It should be understood that when an element, such as a layer, a film, a region, or a substrate is referred to as being “on” or “connected to” another element, it can be directly on or connected to another element, or an intermediate element may also be present. By contrast, when an element is referred to as being “directly on” or “directly connected to” another element, no intermediate element is present. As used herein, being “connected” may refer to a physical and/or electrical connection. Furthermore, being “electrically connected” may refer to the presence of other elements between the two elements.

In addition, relative terms such as “below” or “bottom” and “above” or “top” may be used herein to describe a relationship of one element with another element, as shown in the drawings. It should be understood that the relative terms are intended to encompass different orientations of the device in addition to the orientation depicted in the figures. For example, if a device in a figure is turned over, elements described as being on the “below” side of other elements would be oriented on the “above” side of the other elements. Thus, the exemplary term “below” may include both “below” and “above” orientations, depending on the particular orientation of the drawings. Similarly, if a device in a figure is turned over, elements described as “beneath” or “below” other elements would be oriented “above” the other elements. Thus, the exemplary terms “above” or “below” may include both above and below orientations.

Exemplary embodiments are described herein with reference to cross-sectional views that are schematic illustrations of idealized embodiments. As such, variations from the shapes of the illustrations as a result of, for example, manufacturing techniques and/or tolerances, are to be expected. Thus, embodiments described herein should not be construed as limited to the particular shapes of areas as illustrated herein but are to include deviations in shapes that result, for example, from manufacturing. For example, an area illustrated or described as flat may typically have rough and/or nonlinear features. Moreover, sharp angles that are illustrated may be rounded. Thus, the areas illustrated in the figures are schematic in nature and the shapes thereof are not intended to illustrate the precise shape of an area and are not intended to limit the scope of the claims.

Exemplary embodiments of the disclosure will now be described in detail, examples of which are illustrated in the accompanying drawings. Wherever possible, the same reference numerals are used in the drawings and description to denote the same or similar parts.

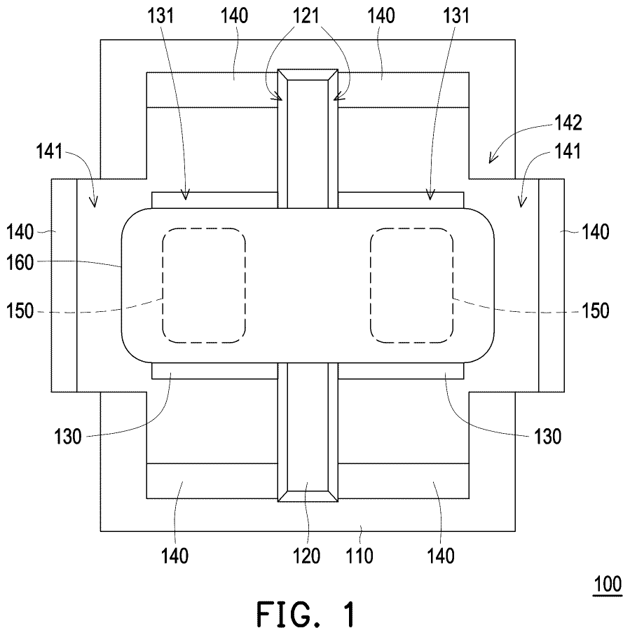

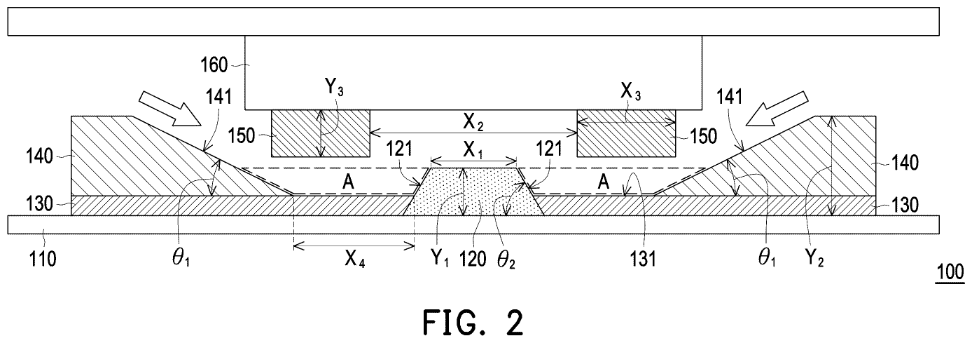

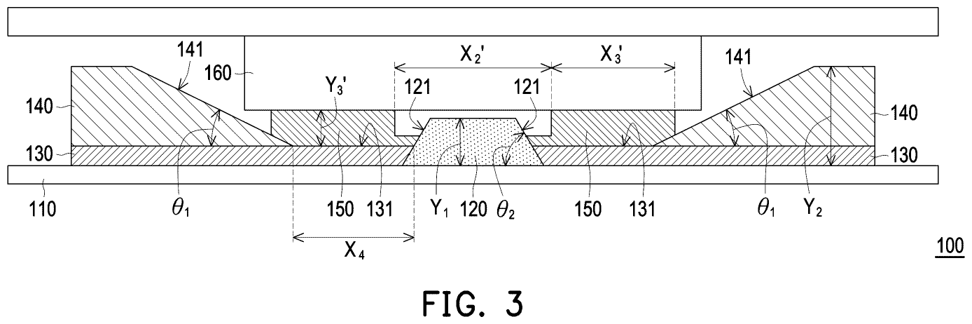

FIG. 1 is a schematic view of a semiconductor light-emitting element of a first embodiment of the disclosure. FIG. 2 to FIG. 3 are schematic views of the semiconductor light-emitting element of the first embodiment of the disclosure during a joining process.

Referring to FIG. 1, FIG. 2, and FIG. 3, a semiconductor light-emitting element 100 of the disclosure includes a substrate 110, an insulating material 120, multiple conductors 130, multiple guide structures 140, multiple solders 150, and a light-emitting module 160. The insulating material 120 is formed on the substrate 110. The conductors 130 are formed on the substrate 110, and are located on opposite sides of the insulating material 120. The guide structures 140 are respectively formed on each of the conductors 130, and are located on opposite sides of the insulating material 120. Each guide structure 140 has a first guide inclined surface 141. The solders 150 are respectively disposed on each of the conductors 130. Each solder 150 is located between the insulating material 120 and the first guide inclined surface 141. The light-emitting module 160 is disposed on the solders 150. The solders 150 are located between the light-emitting module 160 and the conductors 130.

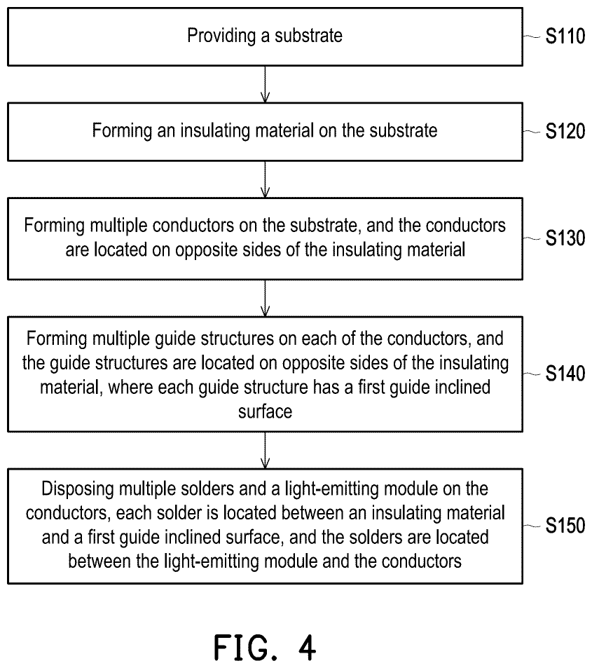

FIG. 4 is a flow chart of a manufacturing method of the semiconductor light-emitting element of the first embodiment of the disclosure.

Further referring to FIG. 4, the manufacturing method of the semiconductor light-emitting element of the disclosure includes following steps. In step S110, a substrate is provided. In step S120, an insulating material is formed on the substrate. In step S130, multiple conductors are formed on the substrate, and are located on opposite sides of the insulating material. In step S140, multiple guide structures are formed on each of the conductors, and are located on opposite sides of the insulating material, where each guide structure has a first guide inclined surface. In step S150, multiple solders and a light-emitting module are disposed on the conductors, each solder is located between the insulating material and the first guide inclined surface, and the solders are located between the light-emitting module and the conductors.

Accordingly, when the solders 150 are disposed on each of the conductors 130, a joining area A between the first guide inclined surface 141 and the insulating material 120 may be accurately positioned by the first guide inclined surface 141, thus effectively avoiding deviation when the solders 150 and the light-emitting module 160 are joined to the conductors 130, which helps reduce situations of short circuit or open circuit, and has extremely high reliability.

In an embodiment, a hardness of the guide structures 140 is greater than a hardness of the solders 150, which ensures that the solders 150 and the light-emitting module 160 may be securely joined to the conductors 130 during the process.

In an embodiment, the guide structures 140 are insulators.

In an embodiment, the guide structures 140 are conductors, increasing the reliability of the solders 150 during joining.

In an embodiment, a first included angle θ₁ between the first guide inclined surface 141 and a plane 131 of the conductors 130 is between 15° and 30°. The obtuse angle enables the first guide inclined surface 141 to effectively guide the joining of the solders 150 in a smoother sliding manner.

In an embodiment, the insulating material 120 has a second guide inclined surface 121.

In an embodiment, a second included angle θ₂ between the second guide inclined surface 121 and a plane 131 of the conductors 130 is between 45° and 60°. The steep insulating material 120 may effectively achieve a blocking effect to effectively avoid short circuit.

In an embodiment, the first included angle θ₁ between the first guide inclined surface 141 and a plane 131 of the conductors 130 is smaller than the second included angle θ₂ between the second guide inclined surface 121 and the plane 131, enabling the solders 150 to be accurately positioned at the joining area A between the first guide inclined surface 141 and the insulating material 120.

In an embodiment, a first height Y₁ of the insulating material 120 is smaller than a second height Y₂ of a sum of each guide structure 140 and each conductor 130, avoiding collision when the solders 150 join to the conductors 130.

In an embodiment, a distance X₂ between the solders 150 before joining is greater than a first width X₁ of the insulating material 120 to avoid the solders 150 contacting a top surface of the insulating material 120, ensuring the solders 150 accurately join to the joining area A.

In an embodiment, a third width X₄ of the exposed conductor 130 is greater than a second width X₃ of the solders 150 before joining to ensure the solders 150 accurately join to the joining area A.

In an embodiment, a third height Y₃ of the solders 150 before joining is greater than a first height Y₁ of the insulating material 120 to ensure the solders 150 accurately join to the joining area A.

In an embodiment, a distance X₂′ between the solders 150 after joining is greater than a first width X₁ of the insulating material 120 to avoid the solders 150 contacting the top surface of the insulating material 120 to ensure the solders 150 accurately join to the joining area A.

In an embodiment, the third width X₄ of the exposed conductor 130 is greater than or equal to a second width X₃′ of the solders 150 after joining to ensure the electrical connection between the conductor 130 and the solders 150.

In an embodiment, a third height Y₃′ of the solders 150 after joining is greater than a first height Y₁ of the insulating material 120 to avoid the light-emitting module 160 colliding with the guide structure 140.

In an embodiment, the second height Y₂ of the sum of each guide structure 140 and each conductor 130 is greater than the first height Y₁ of the insulating material 120 to ensure the solders 150 accurately join to the joining area A.

In an embodiment, the distance X₂ between the solders 150 before joining is greater than the distance X₂′ between the solders 150 after joining.

In an embodiment, the second width X₃′ of the solders 150 after joining is greater than a second width X₃ of the solders 150 before joining.

In an embodiment, the third height Y₃ of the solders 150 before joining is greater than the third height Y₃′ of the solders 150 after joining.

In an embodiment, a buffer space 142 is provided between two adjacent guide structures 140 located at a corner, so that excess material may flow out through the buffer space 142 during the joining process of the solders 150.

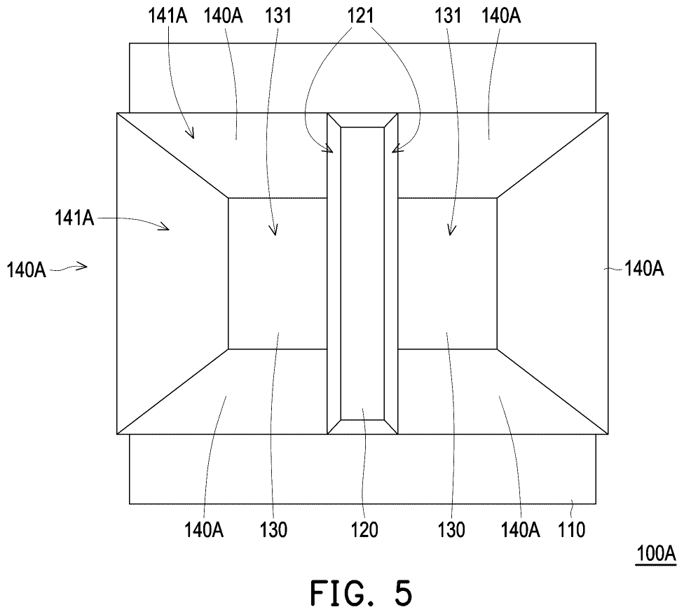

FIG. 5 is a schematic view of a semiconductor light-emitting element of a second embodiment of the disclosure.

Referring to FIG. 5, in a semiconductor light-emitting element 100A of the second embodiment, the guide structure 140A is enclosed in a circle, so that the first guide inclined surface 140A may effectively guide the solders to the joining area.

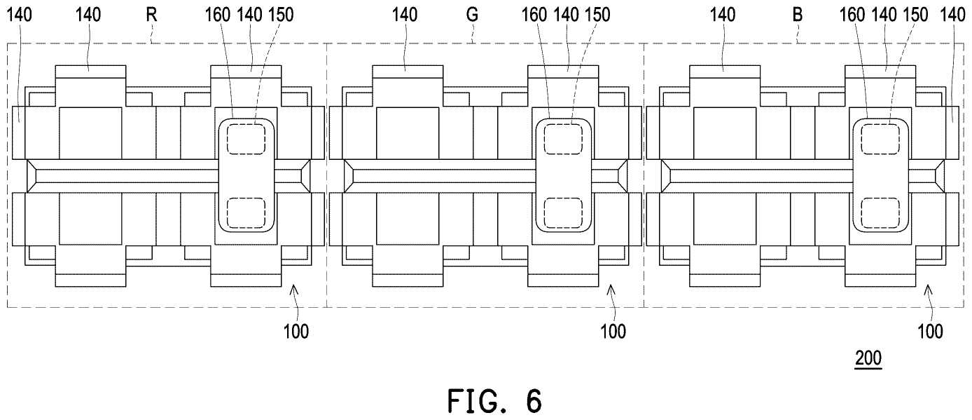

FIG. 6 is a schematic view of the semiconductor light-emitting element of the first embodiment of the disclosure applied as a display module.

Referring to FIG. 6, the semiconductor light-emitting element 100 may be specifically provided with as three primary colors of light R, G, B, to complete a display function of a display module 200.

In summary, in the semiconductor light-emitting element and the manufacturing method thereof of the embodiment of the disclosure, when being disposed on each conductor, the solders may be accurately positioned between the first guide inclined surface and the insulating material by the first guide inclined surface. Therefore, when the solders and the light-emitting module are joined to the conductors, deviation may be effectively avoided, which helps to reduce the situations of short circuit or open circuit, and has extremely high reliability.

What is claimed is:

1. A semiconductor light-emitting element, comprising:
a substrate;
an insulating material, formed on the substrate;
a plurality of conductors, formed on the substrate, and located on opposite sides of the insulating material;
a plurality of guide structures, respectively formed on each of the plurality of conductors, and located on opposite sides of the insulating material, wherein each of the plurality of guide structures has a first guide inclined surface;
a plurality of solders, respectively disposed on each of the plurality of conductors, wherein each of the plurality of solders is located between the insulating material and the first guide inclined surface; and
a light-emitting module, disposed on the plurality of solders, wherein the plurality of solders are located between the light-emitting module and the plurality of conductors.

2. The semiconductor light-emitting element according to claim 1, wherein a hardness of the plurality of guide structures is greater than a hardness of the plurality of solders.

3. The semiconductor light-emitting element according to claim 1, wherein the plurality of guide structures are insulators.

4. The semiconductor light-emitting element according to claim 1, wherein the plurality of guide structures are conductors.

5. The semiconductor light-emitting element according to claim 1, wherein a first included angle between the first guide inclined surface and a plane of the plurality of conductors is between 15° and 30°.

6. The semiconductor light-emitting element according to claim 1, wherein the insulating material has a second guide inclined surface.

7. The semiconductor light-emitting element according to claim 6, wherein a second included angle between the second guide inclined surface and a plane of the plurality of conductors is between 45° and 60°.

8. The semiconductor light-emitting element according to claim 6, wherein a first included angle between the first guide inclined surface and a plane of the conductors is smaller than a second included angle between the second guide inclined surface and the plane.

9. The semiconductor light-emitting element according to claim 1, wherein a first height of the insulating material is smaller than a second height of a sum of each of the plurality of guide structures and each of the plurality of conductors.

10. A manufacturing method of a semiconductor light-emitting element, comprising:
providing a substrate;
forming an insulating material on the substrate;
forming a plurality of conductors on the substrate, wherein the plurality of conductors are located on opposite sides of the insulating material;
forming a plurality of guide structures on each of the plurality of conductors, wherein the plurality of guide structures are located on opposite sides of the insulating material, and each of the plurality of guide structures has a first guide inclined surface; and
disposing a plurality of solders and a light-emitting module on the plurality of conductors, wherein each of the plurality of solders is located between the insulating material and the first guide inclined surface, and the plurality of solders are located between the light-emitting module and the plurality of conductors.

11. The manufacturing method of the semiconductor light-emitting element according to claim 10, wherein a hardness of the plurality of guide structures formed on the substrate is greater than a hardness of the plurality of solders disposed on the plurality of conductors.

12. The manufacturing method of the semiconductor light-emitting element according to claim 10, wherein the plurality of guide structures formed on the substrate are insulators.

13. The manufacturing method of the semiconductor light-emitting element according to claim 10, wherein the plurality of guide structures formed on the substrate are conductors.

14. The manufacturing method of a semiconductor light-emitting element according to claim 10, further comprising:
forming the first guide inclined surface at a first included angle between 15° and 30° relative to a plane of the plurality of conductors.

15. The manufacturing method of the semiconductor light-emitting element according to claim 10, wherein the insulating material has a second guide inclined surface.

16. The manufacturing method of the semiconductor light-emitting element according to claim 15, further comprising:
forming the second guide inclined surface at a second included angle between 45° and 60° relative to a plane of the plurality of conductors.

17. The manufacturing method of the semiconductor light-emitting element according to claim 15, further comprising:
forming the first guide inclined surface at a first included angle relative to a plane of the plurality of conductors; and
forming the second guide inclined surface at a second included angle relative to the plane of the plurality of conductors, wherein the first included angle is smaller than the second included angle.

18. The manufacturing method of the semiconductor light-emitting element according to claim 10, further comprising:
forming the insulating material at a first height on the substrate, wherein the first height is smaller than a second height of a sum of each of the plurality of guide structures and each of the plurality of conductors.
